(19) United States
(12) Patent Application Publication
(10) Pub. No.: US 2015/0216079 A1
(43) Pub. Date: Jul. 30, 2015

(54) COOLING SYSTEM AND ELECTRIC APPARATUS USING THE SAME

(71) Applicant: Hitachi, Ltd., Tokyo (JP)

(72) Inventors: Yoshihiro Kondou, Tokyo (JP); Fumio Takeda, Tokyo (JP); Takayuki Fujimoto, Tokyo (JP)

(21) Appl. No.: 14/422,714

(22) PCT Filed: Sep. 28, 2012
(86) PCT No.: PCT/JP2012/075003

§ 371 Date: Feb. 20, 2015

(51) Int. Cl. H05K 7/20

(52) U.S. Cl. CPC H05K 7/20318

(57) ABSTRACT

There is a problem in a shape of a fin of a boiling heat transfer surface of a conventional cooling system that a boiling nucleus may be stuck to the fin. In contrast, a cooling system of the present invention is provided with a boiling heat transfer surface that vaporizes a refrigerant liquid. Such that the refrigerant liquid forms a thin film at a root and a base portion of a fin for various refrigerants, it is provided with a configuration in which a protruding portion of the fin is inclined from a fin base. Further, it is provided with a configuration in which a notch is provided to the fin base at the fin root. Still further, it is provided with a configuration in which the protruding portion of the fin is cut in a fin base direction.

### TECHNICAL FIELD

The present invention relates to a cooling system on which a heat generating source inside an IT device such as a server, a power supply for an inverter, a motor, and the like is mounted, and an electric apparatus using the same.

### BACKGROUND ART

In recent years, in an IT device such as a server, a power supply for an inverter, a motor, and the like, high density packaging is performed inside a casing due to an improved performance.

By the way, in general, the above-described semiconductor device and the motor, when exceeding a predetermined temperature, may not be capable of retaining performance thereof and may even be broken in some cases. Therefore, temperature control by cooling and the like is necessary, whereby a technique for efficiently cooling the semiconductor device and the motor having an increasing heat value is strongly demanded.

In such a technical background, for a cooling device for cooling the semiconductor device and the motor having an increasing heat value, high performance cooling capability that enables to efficiently cool the semiconductor device and the motor is requested. Note that conventionally, in an IT device such as a server, a power supply for an inverter, a motor, and the like, in general, an air cooling method cooling device has been used in many cases; however, due to the above-described situation, cooling capability thereof is already getting close to a limit, whereby a cooling system of a new method is expected. As one of such methods, for example, a cooling system using a refrigerant such as water is drawing an attention.

Note that as a prior art related to the present invention, for example, in PTL 1, a configuration of a cooling fin is illustrated. Interpreting that a low boiling point refrigerant is water, there is described the configuration in which a height of a fin is from 0.1 to 1.0 mm and a space between the fins is from 0.06 to 0.6 mm converted from a pitch of the fins.

In PTL 2, there is described a configuration of a heat, pipe for cooling a CPU of a personal computer, in which a space between the fins is from 0.1 to 0.35 mm, a diameter of a hole at the top of the fin is from 0.09 to 0.3 mm, and a height of the fin is from 0.05 mm to 0.3 mm.

In PTL 3, there is described a configuration in which a diameter of a hole at the top of the fin is 0.2 mm.

Further, in PTL 4, there is described a configuration in which a distance between the fins is twice or more times of a diameter of a separated bubble and a height of the fin is one to 3.4 times of the diameter of a separated bubble.

### CITATION LIST

### Patent Literature

PTL 1: JP 2010-212403 A

PTL 2: JP 2003-240485 A

PTL 3: JP 2010-256000 A

PTL 4: JP 2005-523414 W

### SUMMARY OF INVENTION

### Technical Problem

In the above described prior art, PTL 1 has the configuration in which a fin base extends vertically, and an orientation of a protrusion of the fin is in a horizontal direction. It is configured such that a boiling nucleus, which ascends by buoyancy of the boiling nucleus, moves upward as the fin is inclined, whereby there is a possibility that the boiling nucleus may be stuck to the fin.

In PTL 2, a recess (notch) is formed at the root of the fin; however, it is provided to a part of a protrusion of the fin and is not to a fin base where a heat flux is high. In PTL 3, the fin has a notch, but it is not at the root. Therefore, similar to the above, it is not provided to a fin base where the heat flux is high.

Further, in PTL 4, a cavity is formed at the root of the fin of a heat transfer pipe; however, it is not provided to a fin base where the heat flux is high.

### Solution to Problem

In order to solve the above-described problem, a cooling system of the present invention includes a boiling heat transfer surface that vaporizes a refrigerant liquid, wherein at a root and a base of a fin of the boiling heat transfer surface, the fin is inclined from the base.

Further, in order to solve the above-described problem, a cooling system includes a boiling heat transfer surface that vaporizes a refrigerant liquid, wherein

at a root and a base of a fin of the boiling heat transfer surface, the fin is tapered.

Further, in order to solve the above-described problem, a cooling system includes a boiling heat transfer surface that vaporizes a refrigerant liquid, wherein at a root and a base of a fin of the boiling heat transfer surface, a notch is provided to the base.

Further, in order to solve the above-described problem, a cooling system includes a boiling heat transfer surface that vaporizes a refrigerant liquid, wherein at a root and a base of a fin of the boiling heat transfer surface, a plurality of cut portions is provided in a fin direction.

Further, in order to solve the above-described problem, an electric apparatus of the present invention is provided with a cooling system including a boiling unit, a condensing unit, and a steam pipe and a liquid pipe connecting the boiling unit and the condensing unit to each other. It is provided with a plurality of cooling fans that cools a device inside the electric apparatus, and the condensing unit is cooled by the plurality of cooling fans.

### Advantageous Effects of Invention

According to the configuration of the present invention, it is possible to realize early generation of the boiling nucleus of the refrigerant and smooth flowing of liquid inflow.

Even in pool boiling in which a heat value is relatively large and an amount of sealed refrigerant liquid is increased such that a heat transfer surface is sufficiently immersed in the refrigerant liquid, the early generation of the boiling nucleus and the smooth flowing of the liquid inflow can be achieved, whereby heat transfer performance can be secured.

### BRIEF DESCRIPTION OF DRAWINGS

FIG. 1 is a sectional view illustrating an overall schematic configuration of a cooling system using a thermo-siphon according to one embodiment of the present invention.

FIG. 2 is an enlarged perspective view including a partial section illustrating a detailed structure of a heat receiving jacket constituting the cooling system using the thermo-siphon according to one embodiment of the present invention.

FIG. 3 is an enlarged view at the root of a fin where a fin portion of a vaporization accelerator plate of a heat receiving jacket according to the present invention is inclined relative to a base.

FIG. 4 is an enlarged view at the root of the fin where the fin portion of the vaporization accelerator plate of the heat receiving jacket according to the present invention is tapered at the base.

FIG. 5 is an enlarged view at the root of the fin where a notch is provided to the base at the root of the fin of the vaporization accelerator plate of the heat receiving jacket according to the present invention.

FIG. 6 is a top view near the root of the fin where a cut portion is provided in a fin direction of the vaporization accelerator plate of the heat receiving jacket according to the present invention.

FIG. 7 is a perspective view illustrating an overall structure of a server mounted on a rack as an example of an electric apparatus to which a cooling system using a heat-siphon, on which a boiling heat transfer surface of the present invention is mounted, is applied.

FIG. 8 is a perspective view illustrating a state in which a lid body is removed for illustrating an example of an internal structure inside a server casing according to an embodiment of the present invention.

FIG. 9 is an exploded perspective view illustrating a power supply for an inverter of the heat-siphon on which a boiling heat, transfer surface according to the present invention is mounted.

FIG. 10 is a side view when the heat-siphon, on which the boiling heat transfer surface according to the present invention is mounted, is applied to a motor.

### DESCRIPTION OF EMBODIMENTS

Hereinafter, an embodiment according to the present invention is described in detail by using the drawings.

### First Embodiment

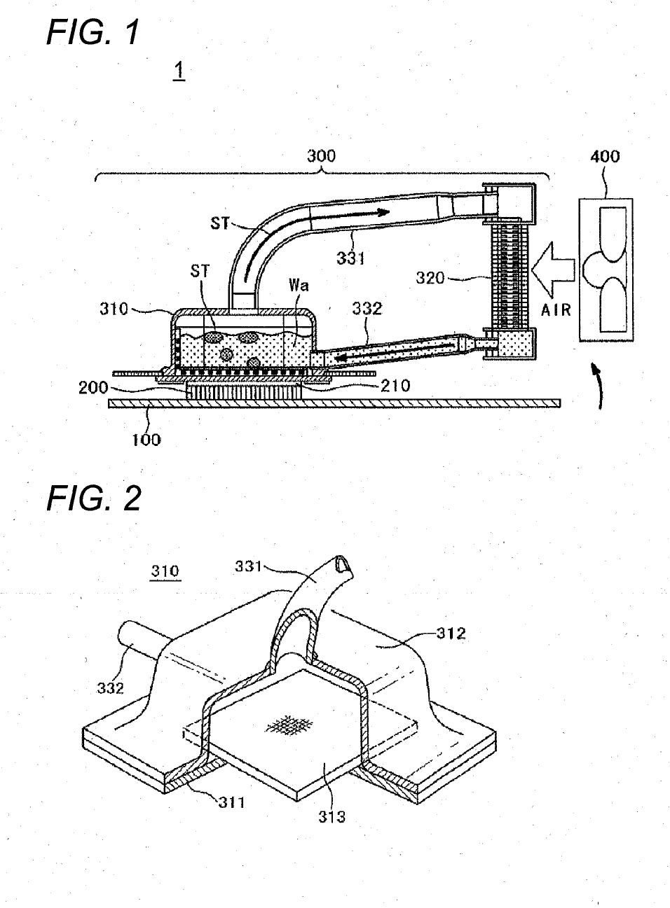

FIG. 1 is a view illustrating an overall structure of a cooling system on which a boiling heat transfer surface is mounted. In the drawing, on a surface of a circuit substrate 100, for example, a semiconductor device 200 such as a CPU, which is a heat generating source, is mounted. Then, on a surface of the semiconductor device 200, a heat receiving jacket 310 constituting a part of a cooling system 300, which uses a thermo-siphon of the present invention, is attached. More specifically, in order to ensure good thermal joining with the heat receiving jacket 310, so-called a heat conductive grease 210 is applied to the surface of the semiconductor device 200. Also, a bottom face of the above-described heat receiving jacket 310 is in contact with and is fixed on the surface thereof by a fixing tool such as a screw (not illustrated). Note that the cooling system 300 is provided with a condenser 320 having a radiator as well as with the above-described heat receiving jacket 310, and a detailed structure of the cooling system 300 is described below. A pair of pipes 331 and 332 is attached therebetween, and inside the pipes 331 and 332 is kept to have a reduced (low) pressure at a level of substantially one tenth of an atmospheric pressure.

The above-described heat receiving jacket 310 constitutes a boiling unit and the above-described condenser 320 constitutes a condensing unit, respectively. Therefore, as described below, there is constituted the so-called thermo-siphon capable of circulating a refrigerant liquid by a phase change of water, which is the liquid refrigerant, without an external power such as an electric pump.

That is, in the cooling system using the above-described thermo-siphon, heat generated in the semiconductor device 200, which is a heat generating source, is transmitted to the heat receiving jacket 310, which is the boiling unit, through the heat conductive grease 210. As a result, in the boiling unit, the water (Wa), which is the liquid refrigerant, is boiled and is evaporated by the transmitted heat under the reduced pressure, and steam (ST) that has been generated is guided from the heat receiving jacket 310 to the condenser 320 through one of the pipes 331. Then, in the condensing unit, as illustrated in the drawing, refrigerant steam is cooled, for example, by air (AIR) sent by a cooling fan 400 and the like, whereby it becomes liquid (water). Subsequently, by gravity, it passes through the other of the pipes 332 and returns again to the above-described heat receiving jacket 310.

Here, a detailed structure of the above-described heat receiving jacket 310 is illustrated in the attached FIG. 2. As illustrated in the drawing, in the heat receiving jacket 310, for example, a lid body 312 formed by throttling metal such as copper or stainless steel into a bowl shape is placed above a rectangular bottom plate 311 constituted of a metal plate having an excellent thermal conductivity such as copper, and a peripheral part thereof is joined by pressure welding, for example. Then, as it is clear from the drawing, rectangular plate-shaped vaporization accelerator plate 313 is attached to an upper surface of the above-described bottom plate 311, and a through hole is formed on each of top and side wall surfaces of the lid body 312. Each of the above-described pair of pipes 331 and 332 is connected thereto.

The vaporization accelerator plate 313 provided with a porous structure surface exerts stable evaporation performance (vaporization performance) as long as the liquid refrigerant is not exhausted. Then, when an input heat value is small, a hole of a porous body is impregnated and filled with the liquid refrigerant; however, when the input heat value is large, the liquid refrigerant filling the hole evaporates and decreases. Therefore, a part having a thin refrigerant liquid film increases inside the porous body, whereby evaporation is further accelerated. It becomes a state in which heat dissipation performance is increased, and an amount of heat transfer is increased. That is, as the input heat value is increased, the evaporation is accelerated depending on a temperature, and the evaporation is accelerated depending on an increase in an amount of steam, whereby the amount of heat transfer is greatly increased as the input heat value becomes larger, and efficiency is improved.

Note that the vaporization accelerator plate 313 is attached to an inner wall side of the bottom plate 311 constituting the above-described heat receiving jacket 310 by welding and the like; however, in the present invention, it is not limited only to this, and the above-described porous structure surface may also be directly formed on an inner wall surface of a copper plate constituting the bottom plate 311.

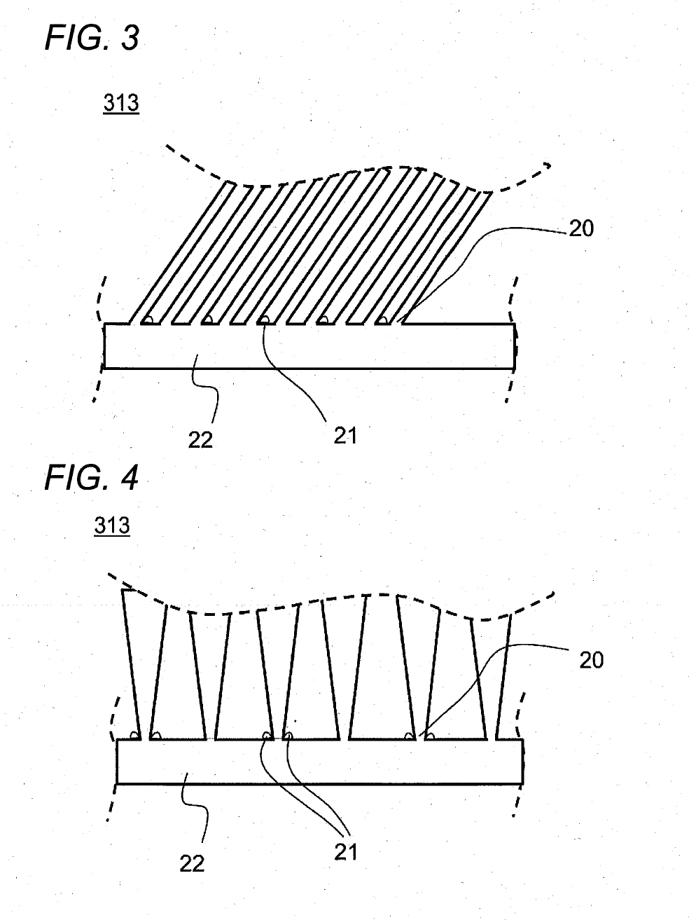

FIG. 3 is an enlarged view illustrating a fin root 20 where a fin portion of the vaporization accelerator plate 313 of a heat receiving jacket is inclined relative to a base 22. For example, a blade is inserted from a side into a fin base, and when a fin is plowed up, the fin may be inclined relative to the base 22 at the fin root 20; however, it is also possible to incline the fin relative to the base in a drawing and extrusion manufacturing method during mass production. At the fin root 20, there are a narrow part and a wide part of an area (space) into which a refrigerant enters between the fin and the base 22. Accordingly, a thin film area and a thick film area of the refrigerant, are caused. In particular, in the thin film area of the refrigerant, a heat flux is raised, and a boiling nucleus 21 is generated early on in the thin film area of the fin root 20. Therefore, early stability of boiling performance can be ensured.

### Second Embodiment

FIG. 4 is an enlarged view illustrating a fin root 20 according to another embodiment in which a fin portion of a vaporization accelerator plate 313 of a heat receiving jacket is tapered at a base 22. It can be processed, for example, by using a metal mold in which the fin portion is tapered at the base 22 in a drawing and extrusion manufacturing method during mass production. At the fin root 20, an area (space) where a refrigerant enters is narrow at both sides of a fin. Accordingly, a thin film area of the refrigerant is caused at the fin root 20, and a boiling nucleus 21 is generated early in the thin film area of the fin root 20. Therefore, early stability of boiling performance can be ensured.

### Third Embodiment

FIG. 5 is an enlarged view illustrating a fin root 20 according to another embodiment in which a notch 23 is provided to a base 22 at the fin root 20 of a vaporization accelerator plate 313 of a heat receiving jacket. It can be processed, for example, by using a metal mold that forms the notch 23 in the base 22 of a fin portion in a drawing and extrusion manufacturing method during mass production. The same configuration can also be achieved by providing a groove of the notch 23 to the base 22 after a fin has been processed by the conventionally used drawing and extrusion manufacturing method. Accordingly, since a distance is short from a back surface of the base 22 where a heat generation body contacts the notch 23 at the notch 23 of the base 22, a heat flux is raised, whereby a thin film area of a refrigerant is generated in this notch 23. A boiling nucleus 21 is generated early in the thin film area of this notch 23. Therefore, early stability of boiling performance can be ensured.

### Fourth Embodiment

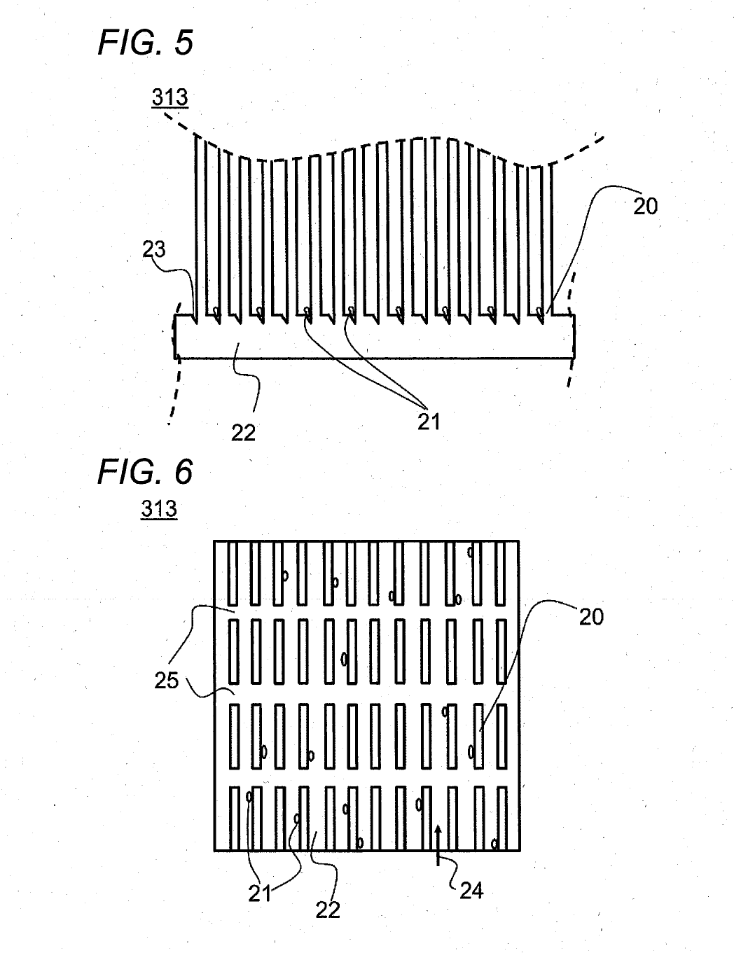

FIG. 6 is a top view illustrating near a fin root 20 according to another embodiment in which a cut portion 25 is provided in a fin direction 24 of a vaporization accelerator plate 313 of a heat receiving jacket. In a case where plow-up is used among the manufacturing methods illustrated in FIGS. 3 to 5, it can be deal with by providing a base with a groove to be the cut portion 25 in advance. In a drawing and, extrusion manufacturing method, the groove to be the cut portion 25 is provided after a fin illustrated in FIGS. 3 to 5 has been processed. Accordingly, a refrigerant is capable of moving not only in the fin direction 24 where a boiling nucleus 21 is generated but also between the fins where the boiling nucleus 21 is not generated. Therefore, boiling is more easily caused on an entire surface of the vaporization accelerator plate 313, and it is possible to achieve high heat transfer performance of a boiling heat transfer surface.

### Fifth Embodiment

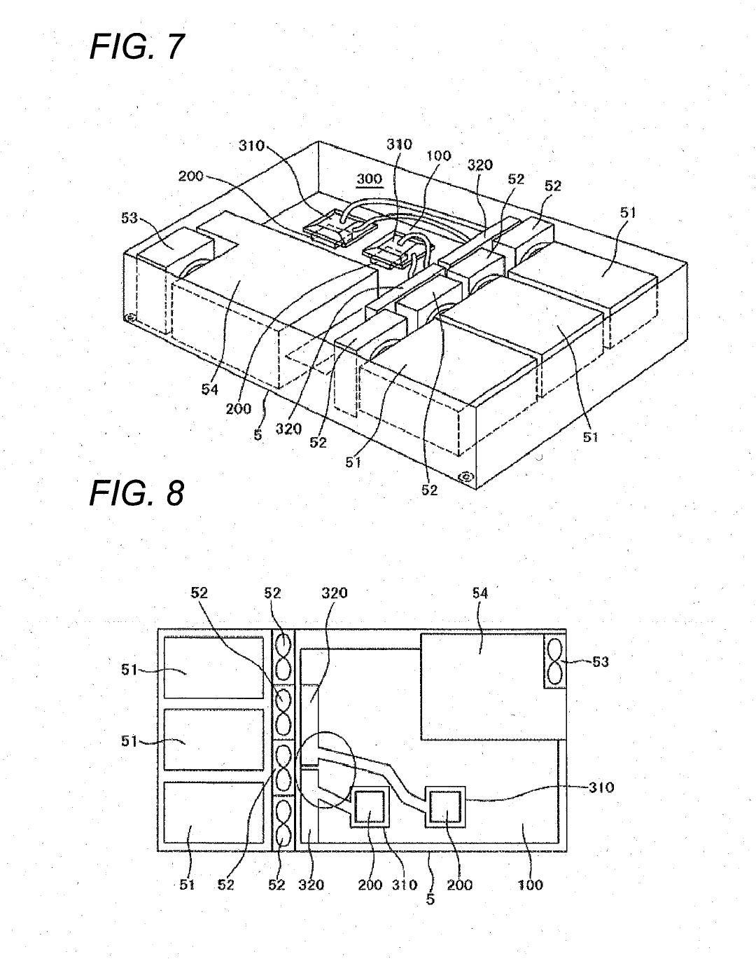

Subsequently, a detailed embodiment of an electric apparatus, on which a thermo-siphon cooling system using the above-described boiling heat transfer surface is mounted, is illustrated in FIGS. 7 and 8.

Inside of server casing 5, for example, as illustrated in attached FIGS. 7 and 8, considering maintainability thereof, a plurality (three in this example) of hard disk drives 51, which is a mass storage device, is provided on one of surfaces (on a front surface side illustrated on the right side of the drawing in this example). Behind it, a plurality (four in this example) of cooling fans 52 for cooling the hard disk drives, which are heat generating sources inside the casing, is attached. Then, in a space with the other of the surfaces of the server casing 5 (that is, a space to the rear), a block 54 that houses LAN, which is an interface with a power supply and a communication means, and the like is provided together with a cooling fan 53. Further, the above-described circuit substrate 100 is arranged in a remaining space, and a plurality (two in this example) of CPUs 200, which is a heat generating source, is mounted on a surface thereof. Note that a perspective view in FIG. 7 illustrates a state in which a lid body is removed.

Then, as it is clear from this drawing, each of the CPUs 200 is provided with a cooling system 300 using the above-described thermo-siphon of the present invention. That is, a bottom face of the above-described heat receiving jacket 310 is contacted with a surface of the CPU 200 through a heat conductive grease applied therebetween, whereby good thermal joining is ensured. Then, according to the present invention, a condenser 320 provided with an offset fin constituting the cooling system 300 is arranged behind the four cooling fans 52 for cooling the above-described hard disk drives. That is, the condenser 320 constituting the cooling system is arranged along a passage of air (cooling air) supplied from outside by the cooling fans 52. That is, the condenser 320 provided with the offset fin is attached in parallel to a row of the above-described cooling fans 52.

In this way, in a structure of the above-described electric apparatus, the cooling fan 52, which is a cooling means of another device incorporated into the casing 5, is used (or shared) as a cooling means (radiator) of the condenser 320 constituting the cooling system 300 in which the thermo-siphon of the present invention is used. According to this configuration, it is possible to efficiently and surely cool the CPU 200, which is a heat generating source inside the chasing, without having a dedicated cooling fan, or in other words, by a cooling system that is relatively simple and low-cost, requires no pump power for driving a liquid, and is excellent in energy-saving. By using the cooling system 300 in which the thermo-siphon of the present invention is used, since it has relatively high heat exchange efficiency and a relatively simple structure, a highly degree of freedom in arrangement becomes possible in an electric apparatus such as a server in which high density packaging is required.

As it is clear from these drawings, each of the condensers 320 constituting the cooling system 300 is arranged so as to cover an exhaust surface of the plurality (two in this example) of cooling fans. Note that according to the configuration of the present invention, even if any of the cooling fans stops due to failure, cooling of the condensers 320 is continued by cooling air generated by the remaining cooling fans. That is, it is preferred as a structure of the cooling system of the electric apparatus since redundancy can be ensured. In particular, as it is illustrated within a circle in FIG. 8, by moving an attachment position of a steam pipe 331, which guides refrigerant steam generated inside the heat receiving jacket 310 to the condenser 320, to ahead toward a side of a small area cooling fan (a cooling fan second from the bottom among the four vertically-aligned cooling fans 52 in the drawing) facing the condensers, which are radiators, it is possible to further improve the redundancy against stopping of any of the cooling fans due to failure.

In this example, three cooling fans are used for two condensing units of the thermo-siphon, whereby 1.5 cooling fans are associated with one condensing unit. At this time, in a case where one cooling fan stops, cooling is performed by the remaining 0.5 fans only. This is a situation equivalent to not being capable of heat dissipating in a two third portion of a radiator of the thermo-siphon condensing unit. In a server system, a certain amount of time is necessary until a normal termination of a system in case of emergency, whereby it is necessary to secure cooling capability during that time. In a conventional radiator of a water cooling method, refrigerant flows uniformly through the entire radiator, whereby in a case where a valid heat dissipation area is decreased by two third, the cooling capability of the refrigerant is also decreased by two third. This decrease in the cooling capability directly contributes to a temperature increase of the CPU. However, in a thermo-siphon system, since it is not possible to condensate steam in a part of the radiator where it is not heat dissipating, whereby as a result, the steam concentrates in the remaining part where it is cooled. The steam that has concentrated to one part has a high flow velocity and flows out a liquid film inside a flat pipe, whereby it contributes to an improvement of condensation performance. The thermo-siphon of this example has a characteristic in that the steam tends to flow more in a flat pipe 323, which is close to a pipe 331 that supplies the steam to the condensing unit. Using this characteristic, by moving the attachment position of the steam pipe 331 to the head toward the side of the small area cooling fan facing the condenser, which is a radiator, it is possible to further suppress a decrease in heat dissipation performance in a case where one of the cooling fans stops. Therefore, by using the thermo-siphon, it is possible to ensure the redundancy with a fewer number of fans.

### Sixth Embodiment

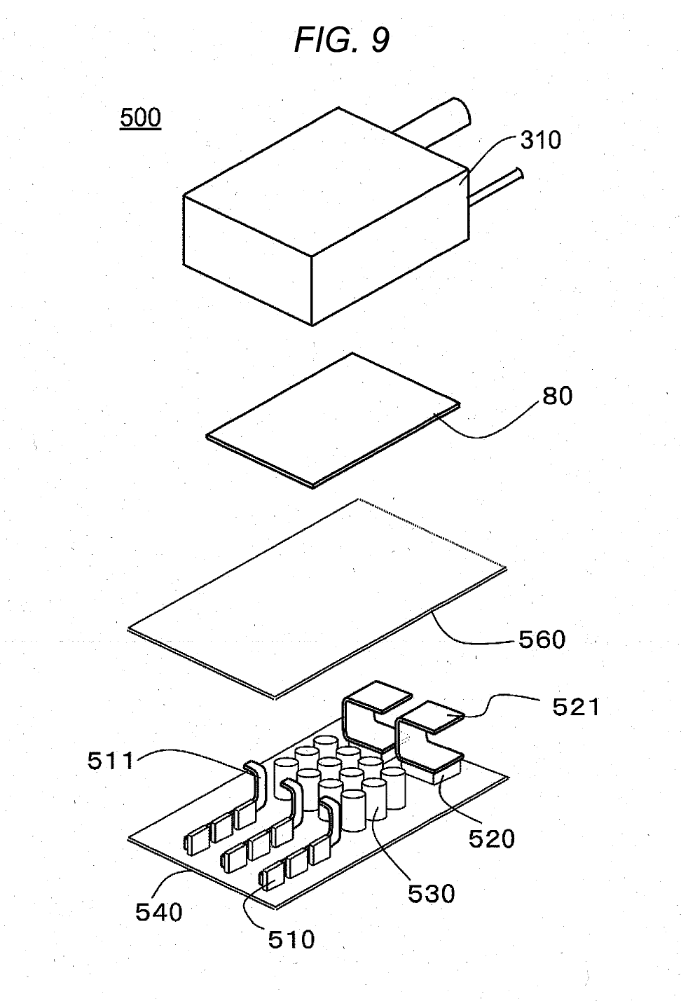

FIG. 9 is a view illustrating a detail of a cooling device of a power supply module for an inverter of another embodiment of the present invention. It is an exploded schematic perspective view illustrating a configuration of the cooling device of a power supply module 500 according to the present invention. As illustrated in FIG. 9, on a power supply substrate 540, a high heat generating transformer 510 having a relatively high heat resistance permissible temperature, a regulator 520, and a low heat generating capacitor 530 having a low heat resistance permissible temperature are mounted. Further, to the transformer 510 and the regulator 520, heat conductive members of flat heat pipes 511 and 521 are attached, respectively. Although not illustrated, one end thereof is attached to a casing sheet metal 560 through grease, a heat transfer sheet, and the like. A heat transfer sheet 80 is provided between the casing sheet metal 560 and a heat receiving jacket 310 of the power supply module, and in order to decrease contact thermal resistance of the heat transfer sheet 80, although not illustrated, a load is held by a spring and the like attached to the module. Also, inside the heat receiving jacket 310, a boiling heat transfer surface, which is a vaporization accelerator plate of the present patent, is attached through the grease, the heat transfer sheet 80, and the like. By using the above-described configuration, it is possible to provide a small-sized and high-density power supply module for an inverter, and with a high performance inverter, it is possible to provide a cooling device capable of dealing with an increase in electric power consumption.

### Seventh Embodiment

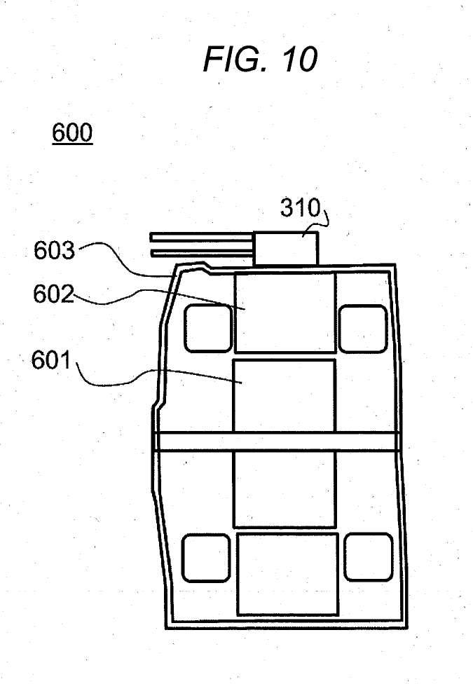

FIG. 10 is a view illustrating a detail of a cooling device of a motor of another embodiment of the present invention. A motor 600 includes a rotor 601, a stator 602, and a casing 603. The casing 603 of the motor 600 may be configured integrally with a casing of a power transmission unit. Heat generated in the stator 602 goes through the casing 603, and a heat receiving jacket 310 is attached to the casing 603. A boiling heat transfer surface, which is a vaporization accelerator plate of the present patent, is attached to inside of the heat receiving jacket 310 through grease, a heat transfer sheet, and the like. By using the above-described configuration, it is possible to provide a high output motor, whereby it is possible to provide a cooling device capable of dealing with an increase in electric power consumption caused by a high performance motor.

1. A cooling system comprising a boiling heat transfer surface that vaporizes a refrigerant liquid, wherein
at a root and a base of a fin of the boiling heat transfer surface, the fin is inclined from the base.

2. A cooling system comprising a boiling heat transfer surface that vaporizes a refrigerant liquid, wherein
at a root and a base of a fin of the boiling heat transfer surface, the fin is tapered.

3. A cooling system comprising a boiling heat transfer surface that vaporizes a refrigerant liquid, wherein
at a root and a base of a fin of the boiling heat transfer surface, a notch is provided to the base.

4. A cooling system according to claim 3, comprising a boiling heat transfer surface that vaporizes a refrigerant liquid, wherein
at a root and a base of a fin of the boiling heat transfer surface, a plurality of cut portions is provided in a fin direction.

5. The cooling system according to claim 1, comprising:
a boiling unit;
a condensing unit; and
a steam pipe and a liquid pipe connecting the boiling unit and the condensing unit to each other.

6. An electric apparatus provided with a cooling system including a boiling unit, a condensing unit, a steam pipe and a liquid pipe connecting the boiling unit and the condensing unit to each other, the electric apparatus further comprising:
a plurality of cooling fans that cools a device inside the electric apparatus, wherein
the condensing unit is cooled by the plurality of cooling fans.

7. The electric apparatus according to claim 6, wherein
an attachment position of the steam pipe to the condensing unit is arranged on a side of a small area cooling fan facing the condensing unit.

8. The electric apparatus according to claim 6, wherein
the plurality of condensing units is cooled by one cooling fan.
